(19) United States
(12) Patent Application Publication
(10) Pub. No.: US 2013/0206221 A1
(43) Pub. Date: Aug. 15, 2013

(54) SOLAR CELL WITH METALLIZATION COMPENSATING FOR OR PREVENTING CRACKING

(71) Applicants: John Anthony Gannon, Palo Alto, CA (US); Radu Raduta, Mountain View, CA (US)

(72) Inventors: John Anthony Gannon, Palo Alto, CA (US); Radu Raduta, Mountain View, CA (US)

(21) Appl. No.: 13/371,790

(22) Filed: Feb. 13, 2012

(51) Int. Cl. H01L 31/0216

(52) U.S. Cl. 136/256

(57) ABSTRACT

Solar cells comprise metallization patterns that compensate for or tend to prevent cracking of the solar cells that might otherwise reduce performance.

### FIELD OF THE INVENTION

The invention relates generally to solar cells.

### BACKGROUND

Alternate sources of energy are needed to satisfy ever increasing world-wide energy demands. Solar energy resources are sufficient in many geographical regions to satisfy such demands, in part, by provision of electric power generated with solar (e.g., photovoltaic) cells.

### SUMMARY

Solar cells and front and back surface metallization patterns for solar cells are disclosed herein,

In one aspect, a solar cell comprises a semiconductor diode structure having a front. surface to be illuminated by light, and an electrically conducting front surface metallization pattern disposed on the front surface of the semiconductor diode structure to provide an electrical contact to the semiconductor diode structure. The front surface metallization pattern includes at least one bus bar, a plurality of fingers attached to the bus bar, and a bypass conductor interconnecting two or more of the fingers to provide multiple current paths from each of the two or more interconnected fingers to the bus bar.

The bus bar may extend in a straight line, with the fingers oriented parallel to each other and perpendicular to the bus bar, and the bypass conductor oriented parallel to the bus bar, Other orientations of the bus bar, fingers, and bypass conductor may also be used.

The bypass conductor may be spaced apart from the bus bar by, for example, about a minimum distance necessary to include between the bypass conductor and the bus bar a desired fraction (e.g., percentage) or more of cracks that form in the front surface of the solar cell on the same side of the bus bar as the bypass conductor and each sever 1 or more fingers, when the solar cell is subjected to about 1000 temperature cycles between about −40° C. and about 85° C. with a cycle period of, for example, about 2 hours. The spacing between the bypass conductor and the bus bar may also be greater than that minimum distance, however.

Alternatively, or additionally, the bypass conductor may be spaced apart from the bus bar by, for example, about a minimum distance necessary such that the power output by the solar cell during normal operation of the solar cell degrades by less than about 15%, or less than about 10%, or less than about 8%, or less than about 5% when the solar cell is subjected to about 1000 temperature cycles between about −40° C. and about 85° C. with a cycle period of for example, about 2 hours. Such normal operation of the solar cell may occur, for example, under direct normal illumination of the solar cell of about 4500 Watts/meter² (W/m²) to about 13,500 W/m² or equivalent illumination. The spacing between the bypass conductor and the bus bar may also be greater than the minimum distance established by the above test, however.

The bypass conductor may be spaced apart from the bus bar by, for example, less than or equal to about 5 millimeters (mm), less than or equal to about 2.5 mm, less than or equal to about 2.0 mm, or less than or equal to about 1.0 mm. Other spacing may also be used.

The width of the width of the bus bar may be, for example, about 5 to about 15 times the width of the bypass conductor. Other ratios of bus bar width to bypass conductor width may also be used.

The widths of the lingers in a region between the bus bar and the bypass conductor may be about the same as their widths in a region on the opposite side of the bypass conductor from the bus bar. Alternatively, some or all of the fingers may have widths in the region between the bus bar and the bypass conductor greater than their widths in the region on the opposite side of the bypass conductor from the bus bar. The width of some or all of the fingers in the region between the bus bar and the bypass conductor may be, for example, about 1 to about 5 times their widths in the region on the opposite side of the bypass conductor from the bus bar.

When configured for operation, the solar cell may include a copper ribbon soldered to the bus bar, and lack any such copper ribbon soldered to the bypass conductor,

The front surface metallization pattern may include at least one island of unmetallized area at least partially surrounded by portions of the bus bar. Such islands may be located at one or more ends of the bus bar, for example. Alternatively, one or more such islands may be located away from the ends of the bus bar and, optionally, entirely surrounded by portions of the bus bar. When configured for operation, the solar cell may include a copper ribbon soldered to the bus bar but not soldered to such islands in or at ends of the bus bar. The front surface metallization pattern need not include any such islands, however,

In another aspect, a solar cell comprises a semiconductor diode structure having a front surface to be illuminated by light, and an electrically conducting front surface metallization pattern disposed on the front surface of the semiconductor diode structure. The front surface metallization pattern includes at least one bus bar and at least one island of unmetallized area at least partially surrounded by portions of the bus bar.

The one or more islands may be entirely surrounded by portions of the bus bar. Islands may be located at one or both ends of a bus bar. Alternatively, or in addition, one or more islands may be located away from the ends of the bus bar, in central locations along the bus bar for example.

Solar cells and solar cell metallization patterns as disclosed herein may be particularly valuable in concentrating photovoltaic systems, in which mirrors or lenses concentrate sunlight onto a photovoltaic cell to tight intensities greater than one “sun.”

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A shows a schematic diagram of an example front surface metallization pattern Dora solar cell and also shows examples of cracks in the solar cell that sever fingers in the metallization pattern and thereby reduce performance of the solar cell.

FIG. 1B shows a schematic diagram of an example back surface metallization pattern for solar cells that may be used, for example, with the front surface metallization patterns of FIG. 1A and of FIGS. 2A- 2F.

FIGS. 2A-2F show schematic diagrams of six example variations of the front surface metallization pattern of FIG. 1A that may tend to prevent or compensate for cracks in the solar cell that sever fingers in the metallization pattern.

FIGS. 3A-3F show, respectively, details A-F of FIGS. 2A-2F.

FIGS. 4A-4F show, respectively, details A-F of FIGS. 2A-2F superimposed on the back surface metallization pattern (shown here in dashed outline) of FIG. 1B.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “parallel or substantially parallel” and to encompass minor deviations from parallel geometries rather than to require that any parallel arrangements described herein be exactly parallel. The term “perpendicular” is intended to mean “perpendicular or substantially perpendicular” and to encompass minor deviations from. perpendicular geometries rather than to require that any perpendicular arrangement described herein be exactly perpendicular. The term “straight” is intended to mean “straight or substantially straight” and to encompass minor deviations from straight geometries.

This specification discloses solar cells (e.g., photovoltaic cells) having front or back surface metallization that compensates for, or tends to prevent, cracks in the solar cell that would otherwise decrease the performance of the solar cell.

Figure IA shows a schematic diagram of an electrically conducting front surface metallization pattern on a solar cell 10. The metallization pattern includes electrically conducting bus bars 15 and electrically conducting fingers 20. In the illustrated example, three bus bars 15 run parallel to one side (the short side) of solar cell 10, and fingers 20 are arranged parallel to each other and attached perpendicularly to the bus bars. Any other suitable number and arrangement of bus bars 15 and fingers 20 in the metallization pattern may be used, instead.

Solar cell 10 comprises a semiconductor diode structure on which the front surface metallization pattern is disposed. A back surface metallization pattern may be disposed on a back surface of solar cell 10 as shown, for example, in FIG. 113 and described further below. The semiconductor diode structure may be, for example, a conventional silicon diode structure comprising an n-p junction, with the top semiconductor layer on which the front surface metallization is disposed being, for example, of either n-type or p-type conductivity. Any other suitable semiconductor diode structure in any other suitable material system may also be used.

In the illustrated example, solar cell 10 is rectangular with its short side, parallel to the bus bars, about 25 mm long and its longer side, perpendicular to the bus bars, about 156 millimeters long. Six such diodes may be prepared on a standard 1156 mm×1156 mm dimension silicon wafer, then separated (diced) to provide solar cells as illustrated. Any other suitable dimensions may also be used.

The front and rear surface metallization patterns on solar cell 10 provide electric contacts to the semiconductor diode structure by which electric current generated in solar cell 10 when it is illuminated by light may be provided to an external load. The electrically conducting bus bars 15 and fingers 20 of the front surface metallization pattern and the electric contacts 25 of the back surface metallization pattern may be formed, for example, from silver paste conventionally used for such purposes and deposited, for example, by conventional screen printing methods. Any other suitable material for forming the bus bars, fingers, and back side contacts, and any other suitable deposition method, may also be used.

Typically, copper ribbons (not shown) are soldered to bus bars 15 on the front surface of solar cell 10, and separate copper ribbons (not shown) are soldered to metal contacts 25 on the back surface of solar cell 10, to provide a conducting path by which the generated electric current may be drawn from the solar cell. The copper ribbons may be soldered to solar cell 10 using a tin/lead solder conventionally used for such purposes, for example, or attached to the front or back surface metallization patterns in any other suitable manner. Any other suitable conductor may be substituted for such copper ribbons.

Two or more of solar cell 10 may be positioned with their long edges adjacent to each other and their front surfaces facing the same direction, and electrically connected in series using the copper ribbons just described. Typically, copper ribbons soldered to bus bars on the front surface of a first solar cell pass beneath an adjacent second solar cell and are soldered to the back surface contacts of the second solar cell. Similarly, copper ribbons soldered to bus bars on the front surface of the second solar cell pass beneath an adjacent third solar cell (located on the opposite side of the second solar cell from the first solar cell) and are soldered to the back surface of the third solar cell. This tabbing pattern may be continued to construct a string of series-connected solar cells of desired length.

The process of soldering copper ribbons to the front surface of solar cell 10 may cause or promote cracking in the front surface of the solar cell near to the bus bars. The soldering may occur, for example, at a temperature of about 150° C. to about 160° C., after which solar cell 10 and the attached copper ribbons cool to ambient temperature. During and upon cooling, a mismatch between the coefficient of thermal expansion of the semiconductor structure and the coefficients of thermal expansion of the solder and the copper ribbon may strain the surface of the semiconductor structure near the bus bars, causing and promoting cracking of the semiconductor surface. Subsequent thermal cycling of the solar cell may cause existing cracks to grow, or cause further cracking in the strained region of the semiconductor surface.

Such thermal cycling and further cracking may result, for example, from use of the solar cell in a concentrating solar application in which the solar cell is illuminated with concentrated solar energy to provide a higher electrical power output. The level of concentration may be, for example about 5 to about 15 times the direct illumination provided by the sun. In such applications the temperature of the solar cell is generally elevated during operation and returns to ambient temperature when not illuminated.

Additionally, cracking of the semiconductor surface near the bus bars may occur as a result of forces applied to the semiconductor surface through the copper ribbon and the solder on the bus bars when the copper ribbons connecting adjacent solar cells are stretched or compressed, for example, during thermal cycling or during tabbing of solar cells as described above.

Cracks caused by processes as described above typically run parallel to the bus bars, or in zigzag paths (as illustrated) parallel to the bus bars.

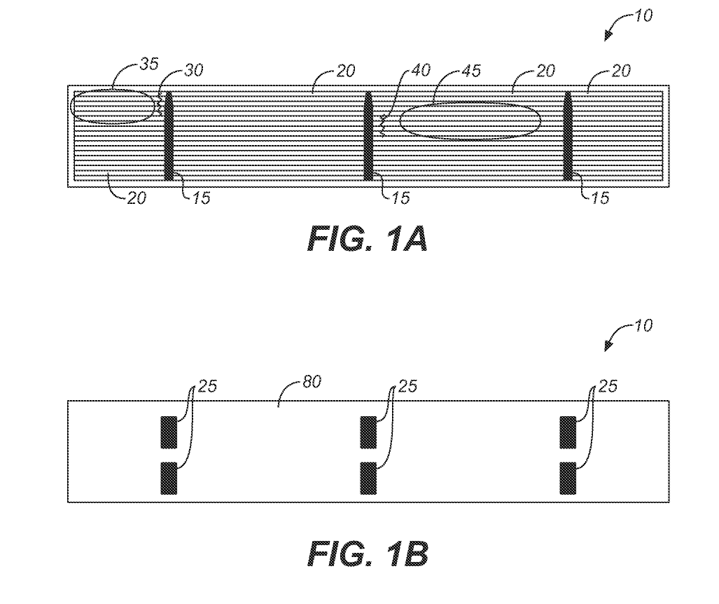

Cracks in the semiconductor surface near the bus bars can sever fingers in the front metallization pattern of solar cell 10 and consequently degrade the performance of the solar Referring again to FIG. 1A, for example, crack 30 adjacent to the leftmost bus bar 15 severs several fingers 20 and consequently isolates a region 35 of solar cell 10 from the bus bars. As a result, region 35 cannot contribute to the electric output of solar cell 10. Similarly, crack 40 on the right hand side of the central bus bar 15 isolates a region 45 of solar cell 10 from the central. bus bar 15. As a result, electric current originating in region 45 may be collected only through the rightmost bus bar 15. This results in longer current paths from region 45, and more electric power loss due to resistance along the current paths, than would otherwise occur.

In addition, copper ribbons that electrically connect adjacent solar cells may break as a result of being stretched or compressed, for example, during thermal cycling or during tabbing of solar cells as described above. This can also significantly reduce the performance of a solar cell or of a string of solar cells.

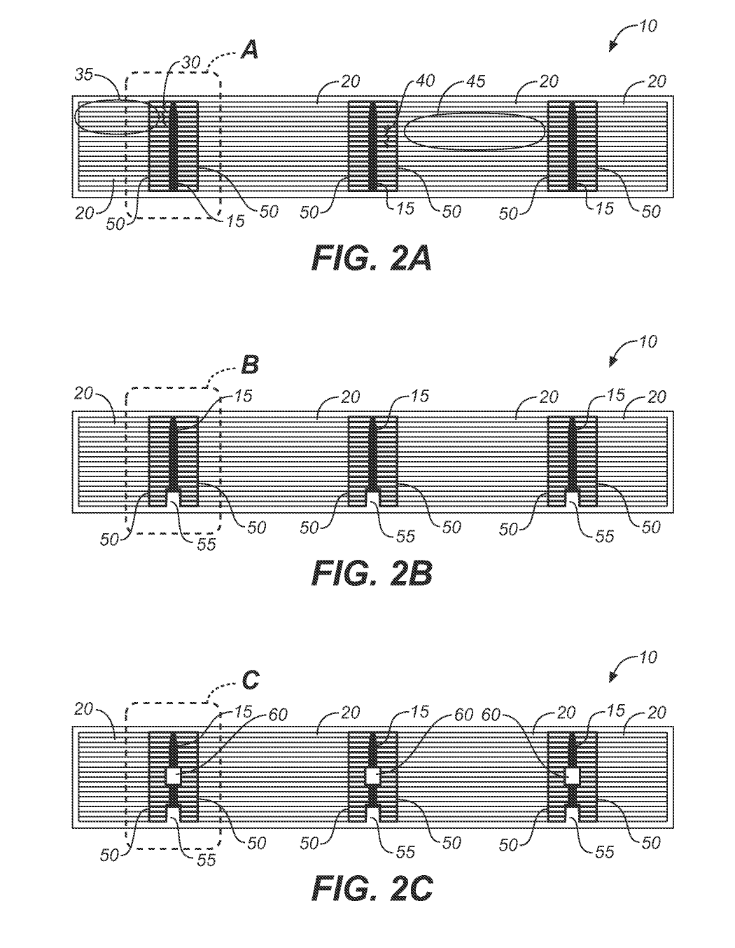

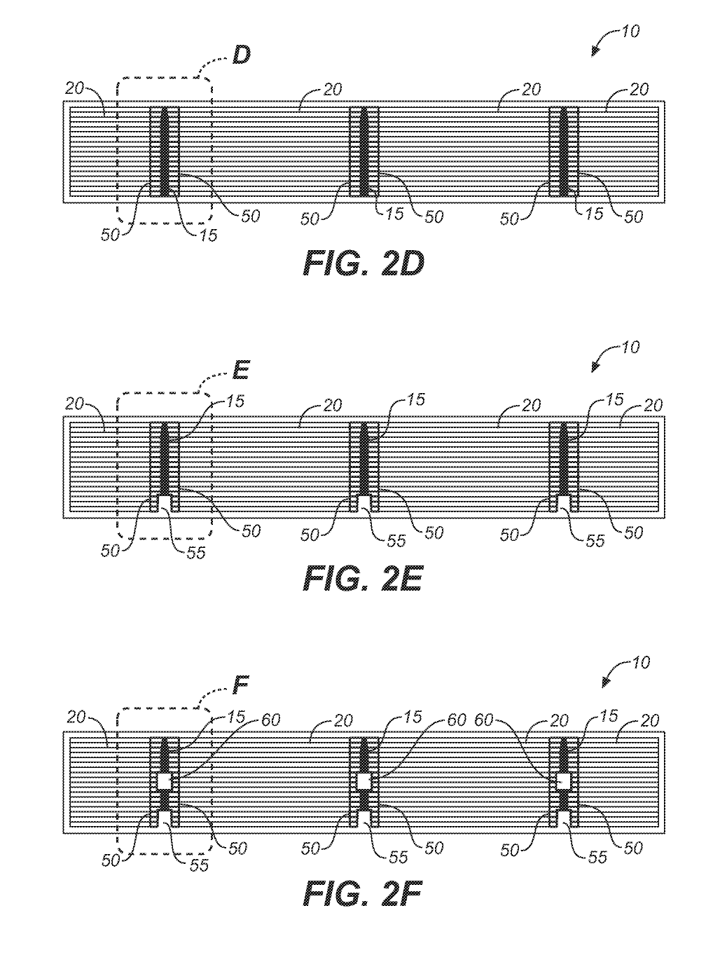

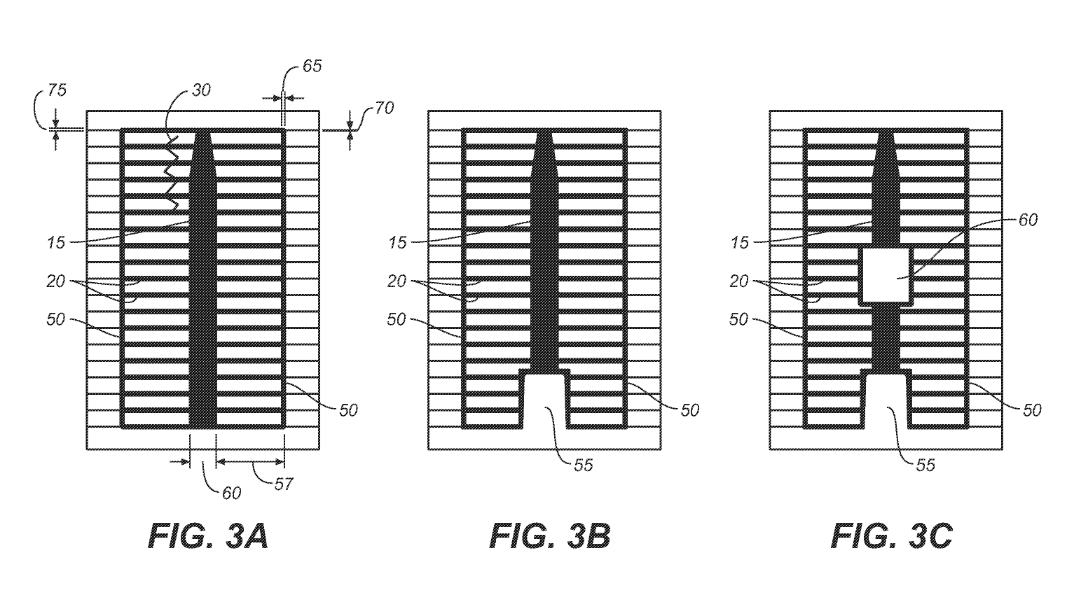

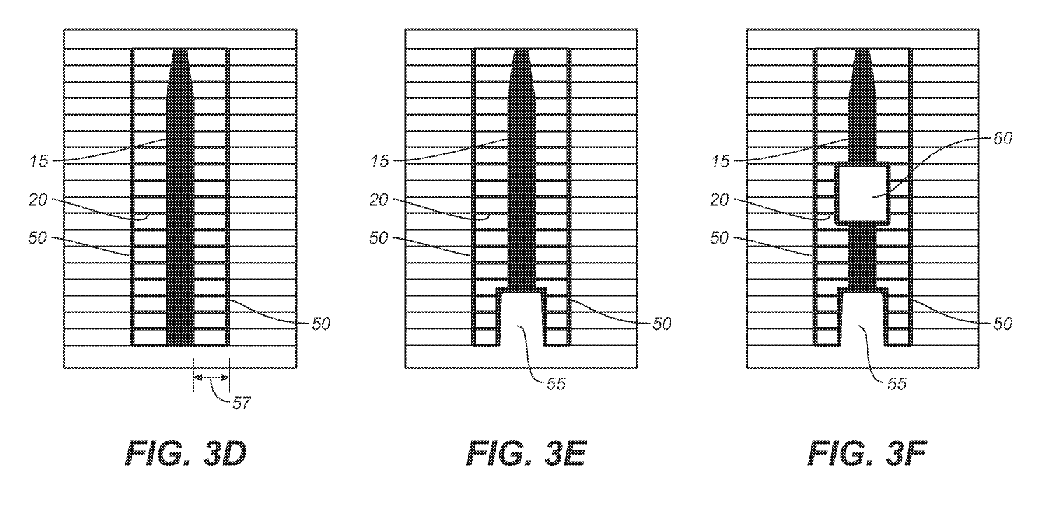

Referring now to FIGS. 2A-2F and to FIGS. 3A-3F, in some variations the front surface metallization pattern of solar cell 10 comprises at least one bypass conductor 50 that interconnects two or more fingers 20 to provide multiple current paths from each of the two or more interconnected fingers to a bus bar 15. Additionally, or alternatively, in some variations the front surface metallization pattern comprises one or more of bus bars 15 that include one or more islands 55 or 60 of unmetallized area at least partially surrounded by portions of the bus bar. Such islands may be, for example, at the end of a bus bar (e.g., islands 55) or away from the ends of the bus bar and (optionally) entirely surrounded by portions of the bus bar (e.g. islands 60). Additionally, or alternatively, the back surface metallization pattern (FIG. 1B) may comprise islands of metallization.

FIGS. 2A-2F and FIGS. 3A-3F show 6 example combinations of two different bypass conductor and finger geometries with three different bus bar island geometries. As further explained below, these examples are not intended to be limiting. Any suitable combination or variation of these features, with any suitable dimensions, may be used. Further, any such suitable combination of bypass conductor, finger, and bus bar island features may be used in combination with any suitable variation of the back surface metallization example of FIG. 1B, or with any other suitable back surface metallization pattern.

### Use of Bypass Conductors

Bypass conductors 50 may provide electric current paths around cracks that occur between the bypass conductors and the bus bars, and consequently reduce the effect on the performance of solar cell 10 of such cracks. Referring to FIG. 2A, for example, a bypass conductor 50 provides alternative current paths between region 35 and leftmost bus bar 15, so that region 35 is not isolated by crack 30 severing some of lingers 20. The alternative current paths run from the severed fingers extending into region 35 through bypass conductor 50 past crack 30 to other fingers that are not severed from the bus bar, then to the bus bar. Another bypass conductor 50 similarly provides current paths between region 45 and central bus bar 15 around crack 40. These alternative current paths around crack 40 may be shorter than the paths from region 45 to rightmost bus bar 15 that would otherwise be required to draw current front region 45.

The illustrated variations show a separate bypass conductor 50 positioned parallel to and on each side of each bus bar 15 and extending about the full length of the bus bar, with each bypass conductor 50 interconnecting every finger 20 on its side of the bus bar. This arrangement may be preferred but is not required. The bypass conductors need not run parallel to the bus bars, they need not extend about the full length of the bus bars, and there need not be a bypass conductor on each side of each bus bar. Further, each bypass conductor 50 interconnects at least two fingers, but need not interconnect all fingers on its side of a bus bar. Any suitable arrangement of bypass conductors, bus bars, and fingers may be used.

As shown in FIGS. 3A-3F, for example, the portion of a finger 20 connecting a bypass conductor 50 to a bus bar 15 may be wider than the portion of the finger on the opposite side of the bypass conductor from the bus bar. Making fingers 20 wider in the region between the bypass conductors and the bus bar allows them to handle additional current flow bypassed from fingers severed by cracks. Some, all, or none of fingers 20 may be made wider in this region. Generally, the further the bypass conductor is placed from its closest bus bar (to bypass more cracks, for example, as described below), the wider the fingers are made in the region between the bypass conductor and that bus bar.

The bypass conductors 50 may be formed, for example, from silver paste and by screen printing as described above for bus bars 15 and fingers 20. Any other suitable material and deposition process may be used instead. Unlike bus bars 15, the bypass conductors 50 are not intended to be soldered to copper ribbons. Because no such soldering occurs at the bypass conductors 50, cracks do not preferentially form near the bypass conductors 50 as they may near the soldered bus bars 15 and fingers 20 are thus not severed from the bypass conductors 50 by cracks. This allows the bypass conductors 50 to provide their bypass function around finger-severing cracks near the bus bars.

Referring for example to FIGS. 3A and 31), the spacing 57 between the bypass conductors 50 and their nearest bus bars 15 may be chosen, for example, to be about the minimum spacing necessary to include between each bypass conductor 50 and its nearest bus bar 15 most or all of the finger-severing cracks that form or are expected to form on the bypass conductor's side of the bus bar. The spacing between the bypass conductors 50 and their nearest bus bars 15 may instead be chosen to be greater than the minimum spacing just described, but such larger spacing might unnecessarily lengthen current paths around finger-severing cracks.

In some variations, the spacing between the bypass conductors 50 and their nearest bus bars 15 is chosen to be about the minimum spacing necessary to include between each bypass conductor 50 and its nearest bus bar 15 most or all of the finger-severing cracks that form on the bypass conductor's side of the bus bar when the solar cell is subjected to about 1000 temperature cycles between about −40° C. and about 85° C. with a cycle period of about 2 hours. The spacing may be chosen, for example, to include, about 60% of the cracks, ≧about 65% of the cracks, ≧about 70% of the cracks, ≧greater than about 75% of the cracks, ≧about 80% of the cracks. ≧about 85% of the cracks, ≧about 90% of the cracks, ≧about 95% of the cracks, or ≧about 99% of such cracks.

In some variations, the spacing between the bypass conductors 50 and their nearest bus bars 15 is chosen such that the electric power output by solar cell 10 under a test illumination level is reduced by less than about 15%, or by less than about 10%, or by less than about 8%, or less than about 5%, when the solar cell is subjected to about 1000 temperature cycles between about −40 C and about 85 C with a cycle period of about 2 hours. The test illumination level may be, for example, solar illumination of the solar cell of about 4500 W/m² to about 13,500 W/m², or of ≧about 4500 W/m², ≧about 5000 W/m², ≧about 5500 W/m², ≧about 6000 W/m², ≧about 6500 NV/m.², ≧about 7000 W/m², ≧about 7500 W/m², ≧about 8000 W/m², ≧about 8500 W/m, about 9000 W/m², ≧about 9500 W/m², ≧about 10,000 W/m², ≧about 10,500 W/m², ≧about 11,000 W/m², ≧about 11,500 W/m², ≧about 12,000 W/m², ≧about 12,500 W/m², ≧about 13,000 W/m², ≧about 13,500 W/m², or an equivalent illumination. Such elevated solar illuminations may be obtained using a solar concentrating geometry, for example, in which. mirrors or lenses concentrate solar radiation onto the solar

Spacing 57 between a bypass conductor 50 and the nearest bus bar 15 may be, for example, ≦about 1.0 mm, ≦about 1.5 mm, ≦about 2.0 mm, ≦about 2.5 ≦about 3.0 mm, ≦about 3.5 mm, about ≦4.0 mm, ≦about 4.5 mm, ≦about 5.0 mm, about 1.0 mm, about 1.5 mm, about 2.0 mm, about 2.5 mm, about 3.0 mm, about 3.5 mm, about 4.0 mm, about 4.5 mm, about 5.0 mm, about 1.0 mm to about 2.5 mm, or about 2.5 mm to about 5.0 mm. 100471 In variations in which the spacing between the bypass conductors and the bus bars is not constant or substantially constant, for example because the bypass conductors and the bus bars are not parallel, the location, configuration, or location and configuration of the bypass conductors may be chosen, for example, to satisfy the crack-inclusion or cell performance requirements just described above.

Referring again to FIG. 3A, in some variations the width 60 of the bus bars may be, for example, about 1.5 mm to about 3.0 mm, about 1.5 mm, about 2.0 mm, about 2.5 mm, about 3.0 mm. The width 65 of bypass conductors 50 may be, for example, about 0.05 mm to about 0.50 mm, or about 0.05 mm, about 0.10 mm, about 0.15 mm, about 0.20 mm, about 0.25 min, about 0.30 mm, about 0.35 mm, about 0.40 mm, about 0.45 mm, or about 0.50 mm. The width 70 of fingers 20 between a bypass conductor 50 and the closest bus bar 15 may be, for example, about 0.05 mm to about 0.5 mm, or about 0.05 mm, about 0.10 mm, about 0.15 mm, about 0.20 mm, about 0.25 mm, about 0,30 mm, about 0,35 mm, about 0.40 mm, about 0.45 mm, or about 0.50 mm. The width 75 of fingers 20 on the opposite side of a bypass conductor from the closest bus bar 15 may be, for example, about 0,05 mm to about 0.50 mm, or about 0.05 mm, about 0.10 mm, about 0.15 mm, about 0.20 mm, about 0.25 mm, about 0.30 mm, about 0.35 mm, about 0.40 mm, about 0.45 mm, or about 0.50 mm.

In some variations, the width 60 of the bus bars may be, for example, about 5 to about 15 times the width of the bypass conductors. In the above and other variations, the width 65 of the bypass conductors 50 may be, for example, about 2.0 to about 10.0 times the width that fingers 20 have outside the region between the bypass conductor and the nearest bus bar. In the above and other variations, some or all of fingers 20 may have a width 75 in the region between the bypass conductor and the closest bus bar about 1.0 to about 5.0 times the width 70 of the fingers outside that region. Inside the region between the bypass conductor and the closest bus bar, fingers 20 may have a width, for example, about equal to that of the bypass conductor.

In the particular example of FIG. 3A, the spacing 57 between bus bar 15 and bypass conductor 50 is about 5.0 mm, bus bar 15 has a width 60 of about 2.0 mm, bypass conductors 50 have widths 65 of about 0.225 mm, and fingers 20 have widths of about 0.225 mm in the regions between bypass conductors 50 and bus bar 15 and widths of about 0.075 mm outside those regions. Hence the bus bar width is about 9 times the bypass conductor width, the bypass conductor width is about 3 times the finger width outside the region between the bypass conductor and the bus bar, and the linger width inside that region is about 3 times the finger width outside that region. The bypass conductor width is about equal to the width of the fingers in the region between the bypass conductor and the bus bar.

in the particular example of FIG. 3D, the spacing 57 between bus bar 15 and bypass conductor 50 is about 2.5 mm, bus bar 15 has a width 60 of about 2.0 mm, bypass conductors 50 have widths 65 of about 0.225 mm, and fingers 20 have widths of about 0.113 mm in the regions between bypass conductors 50 and bus bar 15 and widths of about 0.075 mm outside those regions. Hence the bus bar width is about 9 times the bypass conductor width, the bypass conductor width is about 3 times the finger width outside the region between the bypass conductor and the bus bar, and the linger width inside that region is about 1.5 times the linger width outside that region.

### Use of Unmetallized Bus Bar Islands

Referring again to FIGS. 2A-2F and FIGS. 3A-3F, some of the example front surface metallization patterns shown include bus bars that include one or more islands 55 or 60 of unmetallized area that are at least partially surrounded by portions of the bus bar. These island portions of the bus bars are not intended to be soldered to the copper ribbons to be attached to the bus bars. The islands are “unmetallized” in the sense that they are not printed with silver paste or otherwise prepared for soldering. During the copper ribbon soldering process, solder does not adhere to the islands. However, the “unmetallized” islands may include or be covered with a metal surface, so long as solder does not adhere to it. Islands 55 and 60 may have any suitable shapes and dimensions. Any suitable number and configuration of such islands may be used.

Islands 55 and 60 provide strain relief to copper ribbons soldered to bus bars 15. This strain relief reduces the transmission of forces through the ribbon to the front surface of solar cell 10 and thus may reduce or prevent some cracking of that surface that might otherwise occur. In addition, the strain relief may prevent breaking of the copper ribbons that might otherwise occur.

In addition, because islands 55 and 60 are unsoldered portions of the front surface metallization, the surface of the solar cell in the vicinity of islands 55 and 60 may be less strained than it is along soldered portions of the bus bar, and may provide strain relief for those more strained regions. This strain reduction and strain relief in the solar cell surface may prevent or reduce cracking that might otherwise sever metallization fingers from the bus bars.

A copper ribbon soldered to a bus bar including an island 60 away from the ends of the bus bar typically bridges the island. That is, the copper ribbon is soldered to the bus bar on either side of the island, but not to the surface of the solar cell within the island. As shown in FIG. 3C, for example, such an island 60 may be entirely surrounded by the bus bar, with lateral portions of the bus bar providing a current path around the island. This is not required, however, The bus bar may be separated into two pieces by such an island, with no portions of the bus bar providing a current path around the island. In the latter variation, the bridging copper ribbon electrically connects the two portions of the bus bar separated by the island.

An island 55 at an end of a bus bar may have a length parallel to the long axis of the bus bar of, for example, about 2.0 mm to about 10.0 mm and a width perpendicular to the long axis of the bus bar of, for example, about 1.5 mm to about 3.0 mm. An island 60 away from the ends of the bus bar (centrally located, for example) may have a length parallel to the long axis of the bus bar of for example, about 2.0 mm to about 10.0 mm and a width perpendicular to the long axis of the bus bar of for example, about 1.5 mm to about 3.0 mm.

Although FIGS. 2A-2F and FIGS. 3A-3F show islands 55 and 60 used in combination with bypass conductors 55, that is not required. Bypass conductors may be used without islands, and islands may be used without bypass conductors. Islands 55 and 60 may be also be used with front surface metallization patterns such as that shown in FIG. 1A, for example, without bypass conductors.

### Use of Back Surface Metallization Islands

Referring now to FIG. 1B, in some variations a back surface metallization pattern includes two or more contacts 25 in the form of islands of metallization. In contrast to front surface islands 55 and 60, back surface islands 25 are “metallized” in the sense that they are printed with silver paste or otherwise prepared for soldering. During the copper ribbon soldering process, solder does adhere to metallization islands 25. Other portions 80 of the back surface are not printed with silver paste and not otherwise prepared for soldering. Portions 80 may be metallized with aluminum, for example. Any suitable number and configuration of such back surface metallization islands 25 may be used.

Typically, a copper ribbon is soldered to two adjacent metallization islands 25, bridging the gap between them. The gap between the two metallization islands 25 provides strain relief to the copper ribbon, which may prevent breaking of the copper ribbons that might otherwise occur,

Metallization island contacts 25 may have lengths parallel to the tong axes of the front surface bus bars of about 5.0 mm to about 15.0 mm and widths perpendicular to the long axes of the front surface bus bars of about 1.5 mm to about 3.0 mm. Two adjacent metallization islands 25 may be separated along the tong axis of the front surface bus bars by about 5.0 mm to about 15.0 mm.

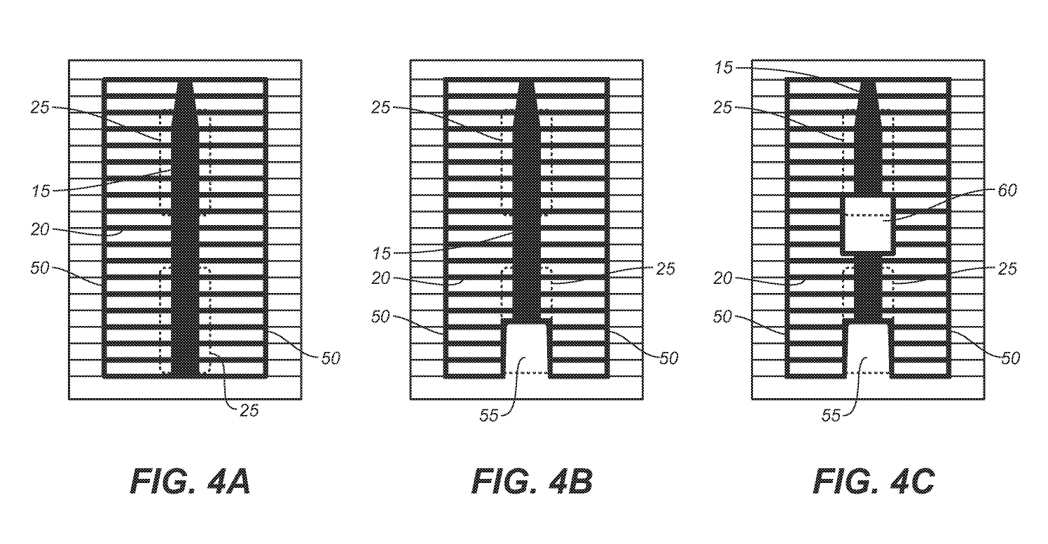

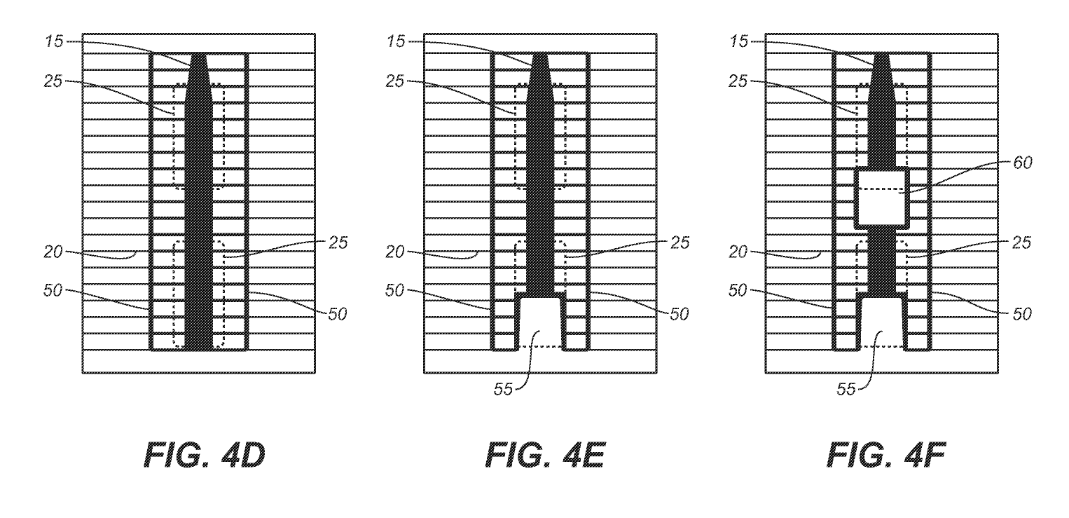

FIGS. 4A-4F show the front surface metallization patterns of details A-F of FIGS. 2A-2F superimposed on the back surface metallization pattern (shown in dashed outline) of FIG. 1B including metallization islands 25. In other variations, the back surface metallization pattern of FIG. 1B may be used with the front surface metallization pattern of FIG. 1A or with any other suitable front surface metallization pattern.

This disclosure is illustrative and not limiting. Further modifications will be apparent to one skilled in the art in light of this disclosure and are intended to fall within the scope of the appended claims.

What is claimed is:

1. A solar cell comprising:
a semiconductor diode structure having a front surface to be illuminated by light; and
an electrically conducting front surface metallization pattern disposed on the front surface of the semiconductor diode structure to provide an electrical contact to the semiconductor diode structure;
wherein the front surface metallization pattern includes at least one bus bar, a plurality of fingers attached to the bus bar, and a bypass conductor interconnecting two or more of the fingers to provide multiple current paths from each of the two or more interconnected fingers to the bus bar.

2. The solar cell of claim 1, wherein the bus bar extends in a straight line, the fingers are oriented parallel to each other and perpendicular to the bus bar, and the bypass conductor is oriented parallel to the bus bar.

3. The solar cell of claim 1, wherein the width of the bus bar is about 5.0 to about 15.0 times the width of the bypass conductor.

4. The solar cell of claim 1, wherein the bypass conductor is oriented parallel to the bus bar and spaced apart from the bus bar by less than or equal to about 5 mm.

5. The solar cell of claim 4, wherein the bypass conductor is spaced apart from the bus bar by less than or equal to about 2.5 mm.

6. The solar cell of claim 1, wherein the widths of at least some of the fingers in a region between the bus bar and the bypass conductor are greater than their widths in a region on the opposite side of the bypass conductor from the bus bar.

7. The solar cell of claim 6, wherein the width of each finger in a region between the bus bar and the bypass conductor is greater than its width in a region on the opposite side of the bypass conductor from the bus bar.

8. The solar cell of claim 7, wherein the width of each finger in a region between the bus bar and the bypass conductor is about 1.0 to about 5.0 times its width in a region on the opposite side of the bypass conductor from the bus bar.

9. The solar cell of claim 8, wherein the width of each finger in a region between the bus bar and the bypass conductor is about 1.5 to about 3.0 times its width in a region on the opposite side of the bypass conductor from the bus bar.

10. The solar cell of claim 1, wherein the bypass conductor is oriented parallel to the bus bar and spaced apart from the bus bar by about a minimum distance necessary to include between the bypass conductor and the bus bar at least about 75% of cracks that form in the front surface of the solar cell on the same side of the bus bar as the bypass conductor and each sever 1 or more fingers, when the solar cell is subjected to about 1000 temperature cycles between about −40° C. and about 85° C. with a cycle period of about 2 hours.

11. The solar cell of claim 1, wherein the power output by the solar cell during normal operation degrades by less than about 15% when the solar cell is subjected to about 1000 temperature cycles between about −40° C. and about 85° C. with a cycle period of about 2 hours.

12. The solar cell of claim 11, wherein the power output degrades by less than about 10%.

13. The solar cell of claim 12, wherein the power output degrades by less than about 5%.

14. The solar cell of claim 11, wherein normal operation of the solar cell occurs under solar illumination of the solar cell of about 4500 W/m² to about 13,500 W/m², or an equivalent illumination.

15. The solar cell of claim 14, wherein normal operation of the solar cell occurs under solar illumination of the solar cell of about 6500 W/m², or an equivalent illumination.

16. The solar cell of claim 1, wherein the front surface metallization pattern comprises at least one island of unmetallized area at least partially surrounded by portions of the bus bar.

17. The solar cell of claim 16, wherein the island is at an end of the bus bar,

18. The solar cell of claim 16, wherein the island is away from the ends of the bus bar and entirely surrounded by portions of the bus bar.

19. The solar cell of claim 1, comprising a copper ribbon soldered to an outward facing surface of the bus bar, wherein no copper ribbon is soldered to the bypass conductor during normal operation of the solar cell.

20. The solar cell of claim 1, wherein the bus bar extends in a straight line, the fingers are oriented parallel to each other and perpendicular to the bus bar, the bypass conductor is oriented parallel to the bus bar, the width of the bus bar is about 5.0 to about 15.0 times the width of the bypass conductor, and the widths of at least some of the fingers in a region between the bus bar and the bypass conductor are about 3.0 to about 5.0 times their widths in a region on the opposite side of the bypass conductor from the bus bar.

21. The solar cell of claim 20, wherein the bypass conductor is spaced apart from the bus bar by less than or equal to about 2.5 mm.

22. A solar cell comprising:
a semiconductor diode structure having a front surface to be illuminated by light; and
an electrically conducting front surface metallization pattern disposed on the front surface of the semiconductor diode structure;
wherein the front surface metallization pattern includes at least one bus bar and at least one island of unmetallized area at least partially surrounded by portions of the bus bar.

23. The solar cell of claim 22, wherein the island is at an end of the bus bar.

24. The solar cell of claim 22, wherein the island is away from the ends of the bus bar and entirely surrounded by portions of the bus bar.
